(19) United States
(12) Patent Application Publication
(10) Pub. No.: US 2013/0043924 A1
(43) Pub. Date: Feb. 21, 2013

(54) Systems, Methods, and Apparatus for High-Speed Signal Buffer Circuitry

(71) Applicant: Donald Edward Romeo, El Segundo, CA (US)

(72) Inventor: Donald Edward Romeo, El Segundo, CA (US)

(73) Assignee: THE AEROSPACE CORPORATION, El Segundo, CA (US)

(21) Appl. No.: 13/211,075

(22) Filed: Aug. 16, 2011

(51) Int. Cl. H03K 5/05

(52) U.S. Cl. 327/288

(57) ABSTRACT

Certain embodiments of the invention may include systems, methods, and apparatus for providing an integrated high-speed signal buffer circuit. According to an example embodiment of the invention, a method is provided for driving a clock signal. The method includes configuring a clock driver circuit with a differential clock buffer output connected to one or more clock lines; matching an operational output resistance of the differential clock buffer output approximately with an input impedance associated with the one or more clock lines; receiving a clock reference signal; applying the clock reference signal to inputs associated with the differential clock driver circuit; and driving the one or more clock lines with the differential clock buffer output.

### FIELD OF THE INVENTION

This invention generally relates to signal buffer circuitry, and in particular, to buffer circuitry for high-speed signal distribution.

### BACKGROUND OF THE INVENTION

Microprocessors and other integrated circuits (ICs) utilize various internally and externally generated signals to implement functions internal to the IC such as synchronous clocks, global reset commands (i.e., power-on resets), data path enable signals, internal memory read/write mode select signals, and other timing or control functions. The timing and control signals can be distributed via multiple point-to-point (i.e., multi-drop configuration) signal distribution networks, or from an origination point to multiple termination points on the IC via routing networks (or clock “tree” nets) that can be classified as configurations such a star topology, a corporate feed topology, hierarchical feed topology, etc. For example, current design practices utilize interconnect traces for high-speed clock distribution. The interconnect traces are typically implemented as micro-meter wide thin-film conductor interconnect traces, which take the form of microstrip or stripline distributed transmission lines with characteristic impedance values that can be controlled by adjustment of interconnect layout trace width, trace separation in the case of a pair of coupled transmission lines (i.e., edge coupled lines or broadside coupled lines), the dimension of the thickness of the insulating thin film material separating the signal traces from one another as well as separating the signal traces from the signal return plane, and the dielectric constant of this insulating material.

Currently, for IC applications using a fundamental clock frequency below 10 GHz, a clock buffer circuit is typically designed to interface to the lumped element model equivalent input capacitance of the microstrip or stripline transmission line. As such, the clock buffer is designed to achieve the lowest practical output impedance in order to reduce the resistive-capacitive (RC) time constants at the clock buffer output. The RC product can be minimized by employing conventional design optimization as applied to the active transistor components and the corresponding active or passive components which dominate the value of clock buffer effective output impedance. However, it can be demonstrated in practice that such an approach does not necessarily lead to an optimum solution for high-speed clock signal distribution. For example, ICs designed with sub-micron feature sizes are capable of achieving pico-second switching speeds, and therefore require high-speed clock circuitry consistent with the timing budgets and margins as required in the range of tens of pico-seconds and currently to a limit of a few pico-seconds. However, when applied to pico-second timing requirements, traditional clock buffer circuit designs using active (i.e., derived from the active transistor characteristics) pull-up and pull-down circuitry exhibit large signal non-linear values of output impedance. As such, in order to achieve optimum switching speeds, the conventional approaches are not capable of achieving a constant value of output impedance over the large signal output swing. A design which is relegated to use a large signal non-linear output impedance results in unequal clock signal rise time as compared to fall time due to the fact that the buffer output resistive-capacitive (RC) time constant for rise time is not equal to that for fall time due to the inherent semiconductor device non-linearities. Therefore, the traditional approach to minimizing the resistive-capacitive product (RC) of the buffer output resistance and interconnect line capacitive loading does not necessarily lead to a solution that provides the requisite signal integrity and low timing jitter of the clock signal as distributed over the entire IC clock tree network due to asymmetries and other artifacts induced (i.e., reflections from the termination load, multi-drop stubs on the clock line, etc.) during the generation of clock signal rise and fall time transitions.

### BRIEF SUMMARY OF THE INVENTION

Some or all of the above needs may be addressed by certain embodiments of the invention. Certain embodiments of the invention may include systems, methods, and apparatus for high-speed signal buffer circuitry.

According to an example embodiment of the invention, a method is provided for driving a clock signal. The method includes configuring a clock driver circuit with a differential clock buffer output connected to one or more clock lines; matching an operational output resistance of the differential clock buffer output approximately with an input impedance associated with the one or more clock lines; receiving a clock reference signal; applying the clock reference signal to inputs associated with the differential clock driver circuit; and driving the one or more clock lines with the differential clock buffer output.

According to another example embodiment, a system is provided for driving a clock signal. The system includes a DC positive supply voltage; a DC negative supply voltage; an in-phase clock buffer output; an out-of-phase clock buffer output; a first transistor of a differential pair having a high side connected to the out-of-phase clock buffer output, wherein the out-of-phase clock buffer output connects to the DC positive supply voltage by a first pull-up resistor; a second transistor of the differential pair having a high side connected to the in-phase clock buffer output, wherein the in-phase clock buffer output connects to the DC positive supply voltage by a second pull-up resistor; a differential clock reference signal for driving respective inputs of the first transistor and the second transistor of the differential pair; and a current sink transistor having a low side connected to the DC negative supply voltage by a third resistor, and a high side connected to low sides associated with the first transistor and the second transistor of the differential pair. The operational output resistance of the differential clock buffer output is configured for approximately matching an impedance associated with a clock line. According to an example embodiment, the operational output resistance of the differential clock buffer output can be configured for approximately matching the characteristic input impedance associated with a distributed element model of an integrated circuit clock transmission line. In an example embodiment, either the DC positive supply voltage or the DC negative supply voltage can be replaced by a connection to the common bias/signal return path.

According to another example embodiment, an apparatus is provided for driving a clock signal. The apparatus includes an in-phase clock buffer output; an out-of-phase clock buffer output; a first transistor of a differential pair having a high side connected to the out-of-phase clock buffer output, wherein the out-of-phase clock buffer output connects to a DC positive supply voltage by a first pull-up resistor; a second transistor of the differential pair having a high side connected to the in-phase clock buffer output, wherein the in-phase clock buffer output connects to the DC positive supply voltage by a second pull-up resistor; a current sink transistor having a low side connected to a DC negative supply voltage by a third resistor, and a high side connected to low sides associated with the first transistor and the second transistor of the differential pair; and a differential clock reference signal for driving respective inputs of the first transistor and the second transistor of the differential pair. The output operational resistance of the differential clock buffer output is configured for approximately matching an impedance associated with a clock line. According to another example embodiment, the operational output resistance of the differential clock buffer output is configured for approximately matching the input impedance associated with a distributed element model of an integrated circuit clock transmission line.

Other embodiments and aspects of the invention are described in detail herein and are considered a part of the claimed invention. Other embodiments and aspects can be understood with reference to the following detailed description, accompanying drawings, and claims.

### BRIEF DESCRIPTION OF THE DRAWINGS

Reference will now be made to the accompanying drawings, circuit diagrams, and flow diagrams, which are not necessarily drawn to scale, and wherein:

FIG. 1 is a block diagram of an illustrative clock buffer and signal distribution circuit, according to an example embodiment of the invention.

FIG. 2 is a circuit diagram of a typical clock buffer.

FIG. 3 is a circuit diagram of an illustrative back-terminated clock buffer, according to an example embodiment of the invention.

FIG. 4 is a circuit diagram of an illustrative current mirror reference, according to an example embodiment of the invention.

FIG. 5 is a circuit diagram of an illustrative back-terminated clock buffer, according to an example embodiment of the invention.

FIG. 6 is a flow diagram of an example method for driving a clock signal, according to an example embodiment of the invention.

FIG. 7 is a time response graph for two different clock buffer embodiments, according to example embodiments of the invention.

### DETAILED DESCRIPTION OF THE INVENTION

Embodiments of the invention will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

According to certain example embodiments of the invention, signal buffer circuits are described in reference to integrated circuit clocking functions; however, the embodiments and approaches presented here may be applied to a wide variety of application and signal types without departing from the invention. For example the terms “clock” or “clocking” can be defined to include the clock signal level within the IC distributed through clock trees, block-oriented or global logic enable signals, global reset commands, memory read, memory write, select enables for embedded memory, and other IC switching functions. The terms “clock lines” may be used to describe the interconnections or transmission lines connecting the buffer outputs to termination points. Example embodiments of the invention may be utilized within an integrated circuit, within a group of integrated circuits, or within a multiplicity of integrated circuits. While it is recognized that giga-hertz data rates and giga-sample-per-second data converter operations (analog-to-digital, digital-to-analog, etc.) can utilize differential clocking of critical sub-circuits (e.g., latched comparators, registers, flip-flops), single-ended clocking may be used for specific applications to reduce wiring routing complexity and power dissipated by the integrated circuit. In this context, example embodiments of the invention can be applied to either differential mode or single-ended clocking configurations by driving the single-ended clock line from a single output of this differential buffer. Various components and design concepts, according to example embodiments of the invention, will now be described with reference to the accompanying figures.

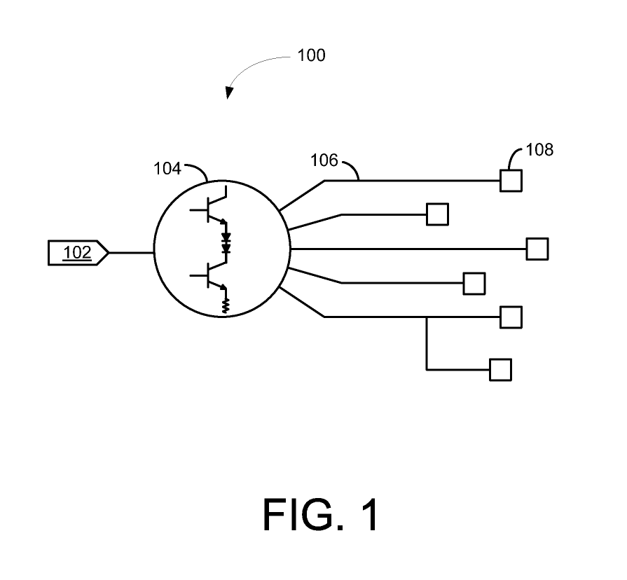

FIG. 1 is a block diagram depicting a clock buffer and signal distribution network 100. For example, a clock signal input 102 may be used in conjunction with clock buffer circuitry 104 to drive clocking lines via transmission lines or distribution interconnections 106. The interconnections 106 may be utilized to deliver the signals to various points of use 108 on the integrated circuit. The points of use 108, for example, may include additional drivers, circuit components, gates, level shifter circuits, clocked comparators, registers, flip-flops, etc.

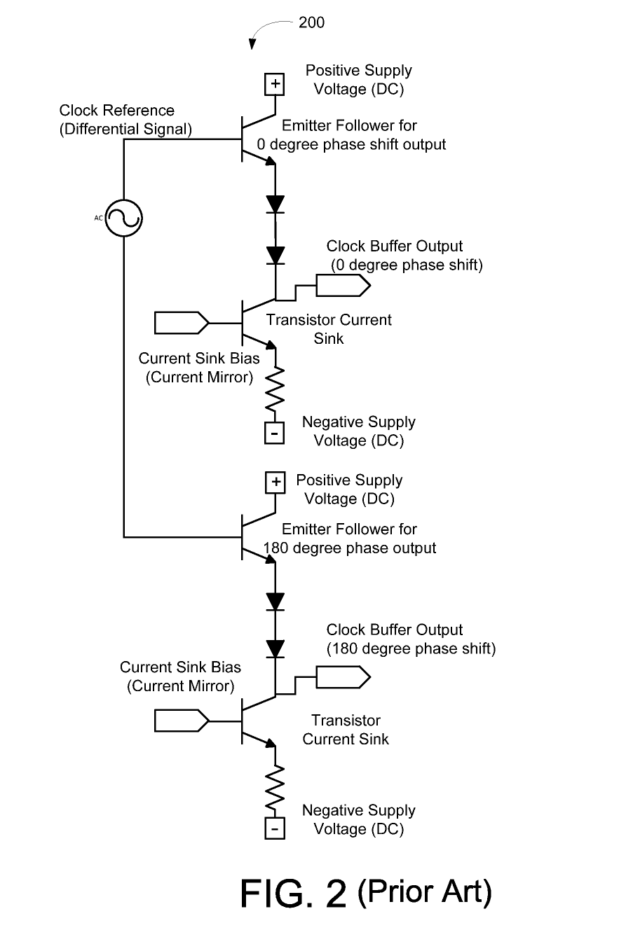

FIG. 2 depicts a typical or traditional clock buffer circuit. In the typical clock buffer circuit, one input of a differential clock reference signal is applied to the base junction of an emitter follower transistor, which may have its emitter coupled to a zero-degree phase shift clock output via a series of diodes. The diodes serve as signal level shifters which are necessary to interface the master clock to the target clocked register circuits. A similar circuit and connection scheme is shown replicated for the other input of the differential clock reference signal, resulting in a clock output with a 180-degree phase shift. The differential outputs of the traditional clock buffer circuit of FIG. 2 are typically used to interface with the integrated circuit clock tree network in high-speed semiconductor integrated circuits. The typical clock buffer outputs are designed to drive capacitive loads of a clock tree at ultra high frequency (UHF) rates and beyond. However, an analysis of the circuit shown in FIG. 2 reveals that the impedance associated with the output is non-linear over the dynamic range. For example, in the switching state of operation, the output impedance of the zero-degree phase shift clock output is low when the top transistor is conducting heavily, but the output impedance is high when the top transistor is not conducting heavily (but with steady state current as set by the emitter resistor of the current sink transistor). The circuit output impedance is also temperature sensitive due to the nature of the transistor emitter-base and junction diode temperature coefficients when operated in forward bias.

From basic transmission line theory, the clock signal impressed or launched upon a transmission line propagates in the forward direction until it reaches one of many transmission line “stubs” or discontinuities within the integrated circuit, at which point a fraction of the signal voltage (or current) is reflected back to the source or driver. The signal propagation velocities in the forward and reverse directions are (for current digital and mixed-signal integrated circuits) virtually identical, and hence the various transmission line “stubs” representing the fan-out feed points of circuits intended as targets of the clock signal buffer within the clock tree will each cause a reflection of the incident clock wave which propagates back to the clock driver source but will be received at the source at various times due to the “time of flight” differences due to the physical distance of each “stub” from the source. These reflected voltage (or current) waveforms can combine to produce delays in the clock leading-edge and trailing wavefronts and detrimental voltage overshoots or undershoots typically beyond the designed voltage waveform specification, which can result in the failure of the target flip-flop or register circuits to achieve synchronization with the master clock signal as it is propagated across the clock tree network within the integrated circuit.

The traditional integrated bulk silicon-based clock buffer 200 of FIG. 2, for example, may have an output impedance that varies from a value of about 13 ohms to about 1000 ohms or greater during the signal transitions. The voltage reflection coefficient for operation over the range of 1-10 GHz is estimated to approach a value of −1, which means that an unacceptably large fraction of the incident voltage is reflected back to the clock buffer circuit output, with the voltage standing wave ratio (VSWR) approaching a value of infinity. This calculated value of reflection coefficient predicts that a large transmission line mismatch exists at the interface from the clock buffer circuit to the transmission line input, and that the end-of-line or load termination can be dominated by the clock input transistor base-emitter capacitance at each destination flip-flop or register clock port input, which is typical for submicron bipolar junction transistor (BJT) and heterojunction bipolar transistor (HBT) devices. The values of the clock input transistor capacitance at the register or flip-flop clock input terminal are likewise non-linear, with significant variation in base-emitter capacitance from a minimum value of depletion capacitance with the transistor in a non-conducting state to a much greater value of capacitance (i.e., diffusion and depletion capacitance) when the transistor begins to transition from a non-conducting to a conducting state.

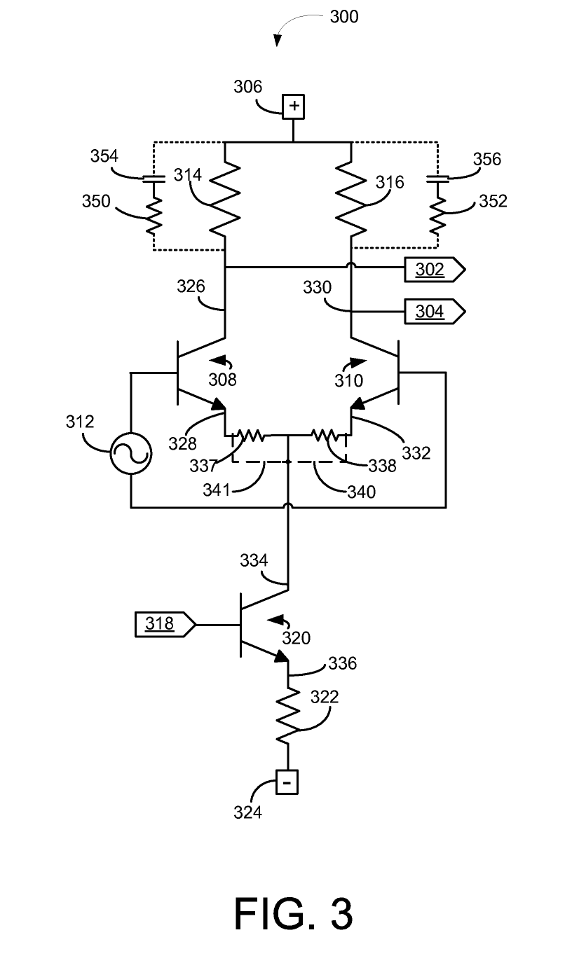

An example embodiment of the invention is represented by the clock buffer 300 of FIG. 3. In this clock buffer 300, and according to an example embodiment, a thin-film material, such as polysilicon or nichrome may be used to realize integrated resistors (currently included as a component by several mixed-signal and radio frequency sub-micron wafer fabrication technologies), and may be used for the clock buffer load devices (such as in pull-up or pull-down resistors 314, 316, 337, 338). In an alternative embodiment, controllable resistors may be implemented using field effect transistors with the source-drain resistance controlled by the gate voltage. According to example embodiments of the invention, the resistance value of the load devices may also define the linear large signal output impedance of the circuit, and the resistance values may be tightly controlled via typical silicon, gallium arsenide, and indium phosphide wafer fabrication processes.

FIG. 3 depicts a clock buffer circuit 300, according to an example embodiment of the invention. The example circuit depicts a clock buffer having an out-of-phase output 302, and an in-phase output 304. The differential output logic format is used primarily to reduce the effects of common mode noise on the differential receiver at the termination. According to an example embodiment, one input of a differential clock reference signal 312 is applied to the base junction of first transistor 308 of an NPN differential pair. The other input of the differential clock reference signal 312 is applied to the base junction of a second transistor 310 of the NPN differential pair. According to an example embodiment of the invention, a first pull-up resistor 314 may connect the out-of-phase output 302 and the collector 326 of the first transistor 308 to a positive supply voltage source 306. A second pull-up resistor 316 may connect the in-phase output 304 and the collector 330 of the second transistor 310 to a positive supply voltage source 306. According to an example embodiment, a first degeneration resistor 337 may provide a connection between the emitter 328 of the first transistor 308 and a collector 334 of a current sink transistor 320. A second degeneration resistor 338 may provide a connection between the emitter 332 of the second transistor 310 and the collector 334 of a current sink transistor 320. According to an example embodiment, the degeneration resistors 337, 338 may be bypassed with respective shorts 341, 340. According to an example embodiment, the emitter 336 of the current sink transistor 320 may be tied to a negative supply voltage source 324 by a current sink resistor 322. According to an example embodiment, the current sink transistor 320 may be biased via the current sink bias input 318.

According to example embodiments of the invention, the resistors 314, 316, 322, 337, 338, may be selected or set for matching the impedance or operational resistance of the clock buffer outputs 302, 304 to the transmission line or clock line impedance over the dynamic range of the output. In an example embodiment, the resistors 314, 316, 322 337, 338 may be set to about 375 ohms. In other example embodiments, the resistors may be set to any convenient resistance ranging from about 100 to about 1000 ohms.

The operational resistance or output impedance of the clock buffer circuit 300 of FIG. 3 may be understood by the following: the clock reference signal 312 may provide a differential signal to the NPN differential pair so that, for example, at an instant in time, the first transistor 308 may be forward biased and conducting (but not in saturation), while the second transistor 310 is in a non-conducting state. In this example, current can flow from the positive supply voltage source 306 through the first resistor 314. In this state, the output voltage at the out-of-phase clock buffer output 302 will be the voltage of the positive supply voltage source 306 minus the voltage drop across the first resistor 314. The current flowing through the first resistor 314 can flow through the collector of the first transistor 308, through either the short 341 or the first degeneration resistor 337, through the current sink transistor 320, through the current sink resistor 322, and to the negative supply voltage source 324. According to an example embodiment, the output impedance or operational resistance of the out-of-phase clock buffer output 302 can be determined by a parallel combination of the first resistor 314 and the series combination of the first transistor 308, either the short 341 or the first degeneration resistor 337, and the current sink resistor 322. However, the collector-emitter resistance of the first transistor 308 will typically be so high that the output impedance or operational resistance of the out-of-phase clock buffer output 302 is determined primarily by the first resistor. The value of the output impedance of the in-phase clock buffer output 304 is dominated by the second resistor 316 (at least when the second transistor 310 is not conducting). According to an example embodiment, and as mentioned above, the high collector-emitter resistance of the first transistor 308 and the second transistor 310 does significantly change the output impedance of the clock buffer output pair 302, 304 during the full voltage swing dynamic range.

Example embodiments of the invention differ from the traditional clock buffer circuitry in several aspects. For example, the clock buffer circuit 300 of FIG. 3 presents a consistent output impedance on the output lines 302, 304 over the signal dynamic range and temperature fluctuations of the circuit. According to an example embodiment of the invention, the clock tree distribution transmission lines may be intentionally designed to increase the clock line interconnect trace series self-inductance (and mutual inductance of a pair of adjacent differential clock lines) in order to achieve an approximation to an ideal distributed transmission line characteristic impedance (as compared to a design approach used to minimize the resistance for the traditional lumped element model capacitance dominated design).

Example embodiments of the invention can provide a clock buffer circuit that can approach performance similar to an ideal voltage source and its series output resistance driving a transmission line of characteristic impedance at a clock frequency of 1 GHz or beyond. For example, typical values of the voltage reflection coefficient for the clock buffer circuit 300 of FIG. 3 are estimated to be between about 0.091 and about 0.130 (i.e., a voltage standing wave ratio (VSWR) between about 1.2 and about 1.3) over the military temperature range of operation. This represents a significant improvement over the expected worst case value of a voltage reflection coefficient of approximately −1 for a clock frequency of 1 GHz or beyond for the traditional clock buffer circuit 200, as shown in FIG. 2.

According to an example embodiment of the invention, a transmission line pair (as in 106 of FIG. 1) may be connected with the out-of-phase output 302 and the in-phase output 304 of the clock buffer 300 for distribution to points of use (as in 108 of FIG. 1). The transmission line pair may be terminated at the point of use or the load with a polysilicon or nichrome thin-film resistor, which may provide good impedance matching and transmission line termination to further minimize the effects of transmission line stubs associated with the fan-out to each group of registers/flip-flops connected in parallel to the clock line pair with regard to reflections a described previously.

According to an example embodiment of the invention, individual clock level shifter circuits may be added at clock transmission line multi-drop points at the input to each group of target register/flip-flop stages (i.e., each group of registers which can include the fan-out along the clock line). The emitter follower (or source follower in the case of an n-channel field effect transistor-based design) level shifters at each target location may further reduce the clock line loading on the master clock buffer circuit because each level shifter may act as a high impedance isolation circuit itself, thereby minimizing the capacitive loading of each flip-flop (i.e., each fan-out feed point). According to an example embodiment of the invention, emitter follower (or source follower) level shifters, positioned at end points of use, may need only to drive transmission line stubs. According to an example embodiment, the level shifters may be completely isolated from the main distribution line(s) by virtue of the fact that each level shifter has negligible reverse signal transmission, even at high frequencies of 1 GHz and beyond.

According to example embodiments of the invention, the operational output resistance of the differential clock buffer is configured to achieve a value approximately equal to a differential transmission line characteristic impedance associated with a clock line interconnection network. This output resistance may also provide back-termination of the differential transmission lines for reflections from the load end back to the driving end of the line (i.e., at the clock buffer output). The additional benefit of the back-termination feature results from the property that, if designed such that the clock buffer output impedance approximately matches the input impedance of the distributed clock transmission line, the end-of-line signal reflections from the load (or multi-drop points) back to the clock buffer outputs will be largely absorbed by the clock buffer output resistance. Therefore, for either single-ended or differential clock distribution networks, the single-ended or differential signal reflected from the load back to the clock buffer will be largely absorbed by its output resistance and therefore will not be reflected again back to the load. This configuration largely avoids the potential for multiple reflections between the transmission line termination load and the clock buffer output. For practical purposes, when used with certain flip-flop or register circuits, or with low noise circuits within analog-to-digital or digital-to-analog converters, it may be necessary to control the rise and fall times of the clock buffer output waveforms (i.e., the two out of phase output waveforms).

Certain example embodiments of the invention may be designed for use with a single-ended distribution transmission network configuration. Other example embodiments may be designed for use with a differential distribution transmission network configuration. A differential clock distribution network, for example, may have an associated “differential mode impedance” associated with a pair of coupled lines and a ground plane or return path. A single-ended distribution, on the other hand, may present a single isolated line impedance that is ½ the impedance as compared with an equivalent differential line of the same geometry, dielectric constant, phase velocity, etc.

FIG. 3 depicts optional additional networks consisting of a first series capacitor, Cp1 354, and a first resistor Rp1 350, placed in parallel with the first clock buffer output resistor 314, and second series capacitor, Cp2 356, and a second resistor, Rp2 352, placed in parallel with the second clock buffer output resistor 316. These optional components may allow the output waveform (302, 304) rise and fall times to be controlled by the approximate value of the time constant equal to the product of the parallel capacitance, Cp, and the sum of the value of the parallel resistor, Rp, and the value of the output resistance. The effect of the this optional network added to the clock buffer is twofold: (1) to allow for a fast-rising step change in the output voltage waveform at the onset of switching with this voltage step change amplitude controlled by the ratio of the value of the two corresponding resistors (i.e, Rp and the corresponding pull-up resistor), and (2) to allow for the realization of a controlled value of clock output waveform rise and fall times and largely independent of the value of the lumped element and parasitic capacitance of the routed clock interconnect traces, which are subject to a degree of uncertainty associated with the specific layout and routing of these clock interconnect traces. In an example embodiment, the placement of the pair of the parallel capacitors, Cp, as connected directly to the positive supply voltage allows for the layout integration of one of the capacitor plates to be in common with the positive supply thin-film conductor metallization bus as a means of controlling and reducing the detrimental effective series resistance (ESR) of each capacitor, Cp.

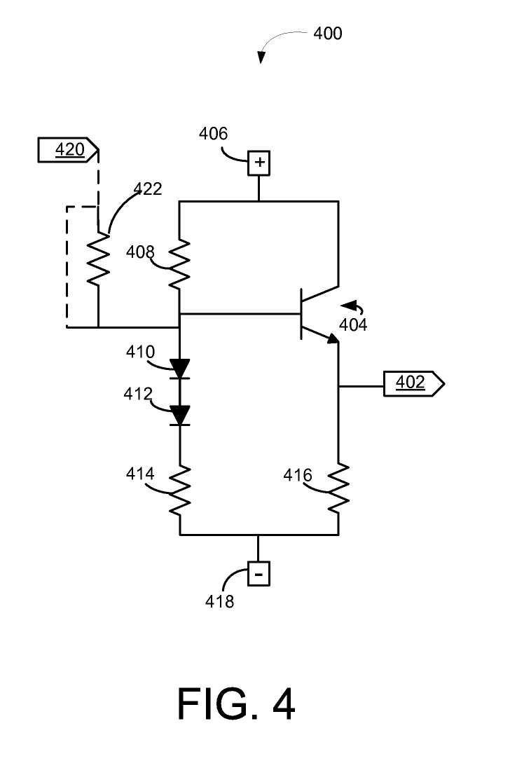

FIG. 4 is a schematic diagram of a current mirror reference circuit 400, according to an example embodiment of the invention. In an example embodiment, the current mirror output 402 can tie directly to the base input 318 of the current sink transistor 320, as shown in FIG. 3. According to an example embodiment, the current mirror reference circuit 400 sets up a reference current which is “mirrored” by the current sink transistor (as in 320 of FIG. 3). In an example embodiment, the current mirror reference circuit 400 includes a current mirror transistor 404 having an emitter tied to the current mirror output 402 and a collector tied to a positive supply voltage source 406. The emitter of the current mirror transistor 404 can tie to a negative supply voltage source 418 via a third resistor 416. In an example embodiment, the biasing of the current mirror transistor 404 may be achieved by providing a current to the base of the current mirror transistor 404. In an example embodiment, the base current may be provided by tying a first resistor 408 from the positive supply voltage source 406 to the base of the current mirror transistor 404, and from the base of the current mirror transistor 404, tying a series combination of diodes 410 412 and a second resistor 414 to a negative supply voltage source 418. In an optional embodiment, an external control 420 may be utilized to set the current of the current sink transistor (as in 320 of FIG. 3). The optional external control 420 may be directly tied to the base of the current mirror transistor 404, or it may be tied to the base of current mirror transistor 404 via a resistor 422. In an example embodiment, this adjustment capability add-on circuit can be implemented using an on-chip current-output digital-to-analog converter using the same or similar technology as used to implement the clock buffer transistor circuitry and/or its output resistor.

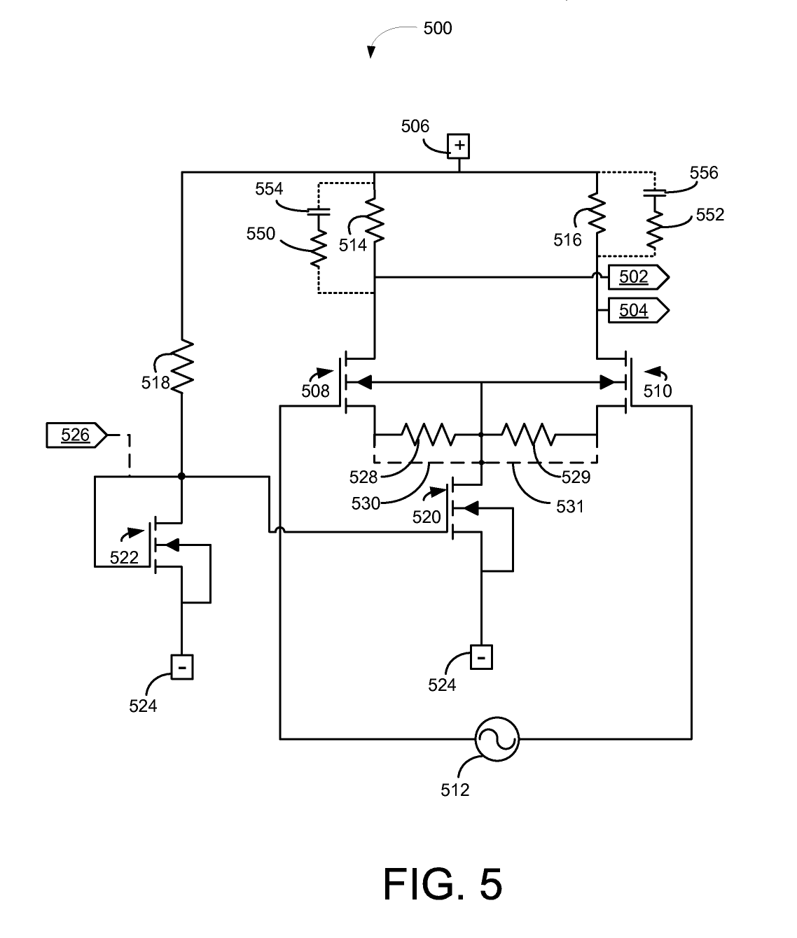

FIG. 5 depicts a back-terminated clock buffer circuit 500, according to an example embodiment of the invention. The circuit depicted in FIG. 5 is similar to the circuit shown in FIG. 3, with the notable exceptions that n-channel field effect transistors (N-MOSFET) 508, 510 may be utilized for controlling the clock signal generation, and the current sink and current mirror functions may be implemented using N-MOSFETs 520, 522—rather than with bipolar junction transistors. According to an example embodiment of the invention, the output impedance of the clock buffer circuit 500 may be set by pull-up resistors 514, 516 when the respective N-MOSFETs 508, 510 of the differential pair are not conducting. For example, the clock reference 512 may provide an oscillating signal, and at an instant in time, the gate of the first N-MOSFET 508 may be positive with respect to the gate of the second N-MOSFET 510. In this example situation, the second N-MOSFET 510 may conduct negligible current, and the voltage at the in-phase clock buffer output 504 may be pulled high to the approximate voltage of the positive supply voltage 506. The output impedance or operational resistance of the in-phase clock buffer output 504, in this condition, may be determined by the second pull-up resistor 516. On the other hand, since the first N-MOSFET 508 is conducting, the output impedance or operational resistance of the out-of-phase clock buffer output 502 (at this instant in time) may be determined by the first pull-up resistor 514 in parallel combination with the following components in series: the first N-MOSFET 508, the first degeneration resistor 528 (or the optional short 530) and the current sink N-MOSFET 520.

According to an example embodiment, the first degeneration resistor 528 may be replaced by an optional short 530, and the second degeneration resistor 529 may be replaced by an optional short 531, as indicated by the dashed lines in FIG. 5. According to example embodiments, the current sink N-MOSFET 520 may be biased to provide the proper drive current for the clock buffer output lines 502, 504, and/or biased to set the output impedance or operational resistance for the respective clock buffer output lines 502, 504 when the first N-MOSFET 508 or second N-MOSFET 510 is conducting. According to an example embodiment, the third degeneration resistor 528 and the fourth degeneration resistor 529 may additionally be utilized to meet the interface requirement to achieve the proper input voltage drive which is translated to the clock buffer output lines 502, 504, and/or to set the output impedance for the respective clock buffer output lines 502, 504 when the first N-MOSFET 508 or second N-MOSFET 510 is conducting.

In an example embodiment, a current mirror bias N-MOSFET 522 may be utilized to set the current in the current sink N-MOSFET 520. According to an example embodiment, the drain of the current mirror bias N-MOSFET 522 may be tied to the positive supply voltage 506 via a third resistor 518, and the source of the current mirror bias N-MOSFET 522 may be tied to the negative supply voltage 524. According to an example embodiment, the drain of the current mirror bias N-MOSFET 522 may be tied to its gate, and this same connection may provide the biasing voltage for connecting to the gate of the current sink N-MOSFET 520. In an optional embodiment of the invention, an external control 526 may be tied to the gate of the current sink N-MOSFET 520 for providing control of the current and/or impedance associated with the current sink N-MOSFET 520.

As in FIG. 3, FIG. 5 depicts optional additional networks consisting of a first series capacitor, Cp1 554, and a first resistor, Rp1 550, placed in parallel with the first clock buffer output resistor 514, and second series capacitor, Cp2 556, and a second resistor, Rp2 552, placed in parallel with the second clock buffer output resistor 516. These optional components may allow the output waveform (502, 504) rise and fall times to be controlled by the approximate value of the time equal to the product of the parallel capacitance Cp, and the sum of the values of the parallel resistor, Rp, and pull-up output resistor. According to an example embodiment, a similar approach can be used with the MOSFET clock buffer, in which the parallel resistors (554, 556) each can be implemented with a thin film resistor material or by a P-channel MOSFET or by an N-channel MOSFET biased in a linear mode of operation approximating the characteristics of passive thin film resistor.

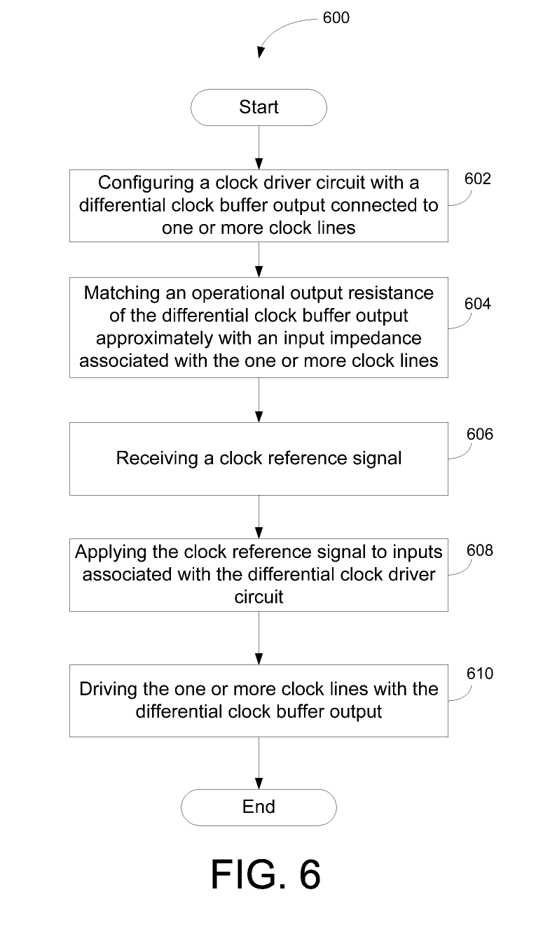

An example method 600 for driving a clock signal will now be described with reference to the flow diagram of FIG. 6. The method 600 starts in block 602, and according to an example embodiment of the invention, includes configuring a clock driver circuit with a differential clock buffer output connected to one or more clock lines. In block 604, and according to an example embodiment, the method 600 includes matching an operational output resistance of the differential clock buffer output approximately with an impedance associated with the one or more clock lines. In block 606, and according to an example embodiment, the method 600 includes receiving a clock reference signal. In block 608, and according to an example embodiment, the method 600 includes applying the clock reference signal to inputs associated with the differential clock driver circuit. In block 610, and according to an example embodiment, the method 600 includes driving the one or more clock lines with the differential clock buffer output. The method 600 ends after block 610.

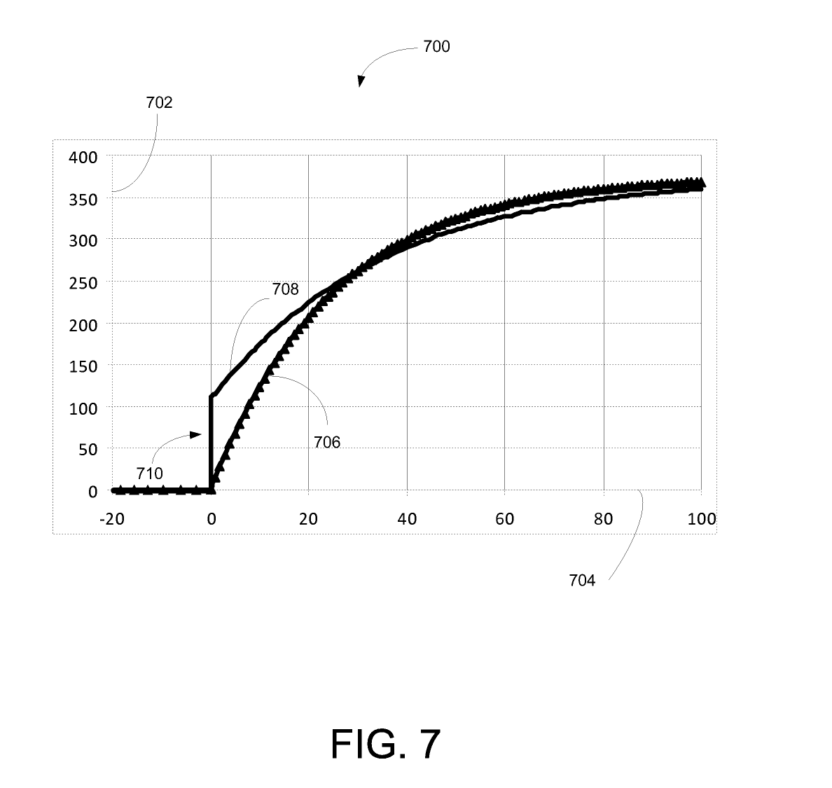

FIG. 7 shows example output waveform responses 700 for two different embodiments of the invention. The y-axis 702 in FIG. 7 represents the buffer circuit output voltage in units of millivolts, and the x-axis 704 represents time in units of picoseconds. The two curves 706 708 are calculated inverse Laplace transforms based on parameters associated with the buffer circuit embodiments. According to a first example embodiment, the first curve 706 shown with triangular markers represents the output time response (as measured at outputs 302 304 in FIG. 3) to a step input (as may be present at input 312 in FIG. 3), but without optional capacitors and resistors 350 352 354 356 present. According to an example second embodiment, the second curve 706 of FIG. 7 represents the output time response (as measured at outputs 302 304 in FIG. 3) to a step input (as may be present at input 312 in FIG. 3) with optional capacitors 354 356 and resistors 354 356 present.

According to example embodiments, and as calculated via the inverse Laplace transforms, the second curve 708 output voltage waveform contains a step response 710 at time t=0+, followed by an exponential curve 708 with time-constant that is set by the components R1 (as in 314 FIG. 3), R2 (as in 350 FIG. 3) and Cp (as in 354 FIG. 3). For example the exponential portion of the second curve 706 may be set by the time-constant (R1+R2)*Cp. In contrast, the first embodiment (as shown in FIG. 3 without the optional capacitors 354 356 and resistors 354 356 present) may have an output voltage waveform depicted by the first curve 706.

According to an example embodiment, the values for Rl/R2 may be a matter of choice, and consequently the amplitude of the output voltage step for the second embodiment at t=0+ can be set so that any following logic circuit (e.g. the diff latching stage following a diff comparator input stage) does not need full differential voltage overdrive necessary to settle. For example, it is known behavior for a differential latching comparator that only a small differential input voltage is needed for latching, and a comparator can switch and settle with less than the full source voltage swing.

For example, as a general rule of thumb, a factor of 10:1 of current difference is needed for switching states for two transistors in a differential pair (as may be present in the termination circuitry for which that the clock buffer provides a switching signal). Therefore, the minimum output voltage from the clock buffer circuit that may need to be received as an input for switching a downstream comparator may determined as follows: Vin (min)=(kT/q) In (10*Ic/Ic)=0.026V*ln(10)=0.0598V, or approximately 60 mV. In general, 120 mV may be used as the voltage switching criteria to provide voltage margin to overcome the effects of component parameter mismatches in the symmetrical differential circuit leading to non-ideal common mode effects. According to the first embodiment (without optional capacitors 354 356 and resistors 354 356 present), based upon a 120 mV (out of a total 350 mV) swing, the time necessary to reach 120 mV out of a 350 mV swing is shown by curve 706 of FIG. 7 to be 10 pS. Assuming a sine wave sampling process, the maximum switching frequency may be determined as: fmax=1/(4*tmin)=25 GHz.

In contrast, the second embodiment, (with optional capacitors 354 356 and resistors 354 356 present, as shown in FIG. 3, or with optional capacitors 554 556 and resistors 550 552 present, as shown in FIG. 5) the ratio of R1 354 and R2 356 may be set to meet the minimum requirement of 120 mV. The second embodiment has a step response output at t=0+, and curve 708 in FIG. 7 shows the time necessary to reach 120 mV is 2 pS. The maximum switching frequency may be estimated as: fmax=1/(4*tmin)=1/(4*2 pS)=125 GHz. Therefore, according to example embodiments of the invention, the addition of the capacitors 354 356 and resistors 354 356 in the second embodiment may result in a 5:1 switching speed improvement over the first embodiment.

Example embodiments of the invention may utilize silicon bipolar junction transistors, silicon-germanium heterojunction bipolar transistors (HBTs), gallium arsenide HBTs and indium phosphide HBTs.

Example embodiments of the invention may be used in clock tree distribution networks for UHF data rates and beyond. Features of the invention may utilize highly linear lumped element devices to define the output impedance of the clock buffer, which may exhibit very low temperature sensitivity and whose operation is virtually independent of clock signal dynamic range. In example embodiments, the use of a clock tree network is intentionally designed to increase the distributed self inductance (and mutual inductance of a clock signal pair of traces) in order to minimize or “tune-out” the effects of transmission line capacitance and to provide an improved match to the clock buffer output impedance. Example embodiments provide the option to implement the functionality of power dividers located at arbitrary distances from the clock driver signal source along the branches of the clock tree network. Candidate applications for clock power dividers may include signal drops (i.e., multi-drops) at points along the transmission line of the clock tree branch. The power divider can be implemented using lumped element resistor divider terminations or coupled-line microwave frequency power dividers at each drop, so that power sharing along the clock tree branches is optimized. Example embodiments of the invention provide the option of utilizing precision resistive-capacitive time delay elements within the clock trees. For example, lumped element thin-film resistor and capacitor elements may be utilized to provide for fine adjustment and compensation of clock skew along the clock tree branches. This fine adjustment of time delay can be fixed or continuously variable using active linear transistor switches to increase or decrease the effective time constants using electronic control of the transistor switch on-resistance characteristics.

Example embodiments of the invention may utilize semiconductor technologies for high-speed operation, namely Si-Ge HBT digital logic, digital-to-analog and analog-to-digital converters, GaAs HBT digital logic, GaAs HBT digital-to-analog and analog to digital converters, InP HBT digital logic, InP HBT digital-to-analog and analog to digital converters, etc. Example embodiments may utilize sub-micron CMOS circuitry, especially those designs which use the current mode logic format. Example embodiments may utilize field-effect transistors in place of bipolar transistors.

Example embodiments of the invention may provide both giga-bit rate digital logic circuits as well as high conversion rate (i.e., giga-sample per second) digital-to-analog and analog-to-digital converter devices.

According to an example embodiment of the invention, a method for driving a clock signal is provided. The method can include configuring a clock driver circuit (300) with a differential clock buffer output (302, 304) connected to a clock transmission line (106); matching an operational resistance of the differential clock buffer output (302, 304) approximately with an impedance associated with the clock line (106); receiving a differential clock reference signal (312); applying the differential clock reference signal (312) to inputs associated with the differential clock driver circuit (300); and driving the clock line (106) with the differential clock buffer output (302, 304). Example embodiments may include applying the differential clock reference signal (312) to inputs associated with the differential clock driver circuit (300), including applying the differential clock reference signal (312) to base inputs of a differential transistor pair (308, 310). Example embodiments may include biasing the differential transistor pair (308, 310) for operation in a forward active mode while conducting.

In an example embodiment, receiving the clock reference signal (312) includes receiving an alternating current signal having a fundamental frequency in the range of about 300 MHz (i.e., 1 m free space wavelength) to about 300 GHz (i.e., 1 mm free space wavelength) for driving the clock transmission line (106) with an alternating current signal having a fundamental frequency in the range of about 300 MHz to about 300 GHz. According to an example embodiment, configuring a clock driver circuit (500) includes configuring a back termination having a controllable resistance (520). In an example embodiment, configuring the back termination comprises configuring an N-channel MOSFET (N-MOSFET) (520), or alternatively a P-channel MOSFET for controlling resistance associated with at least a portion of the back termination. According to an example embodiment, matching the operational resistance of the differential clock buffer output (302, 304) approximately with a characteristic impedance associated with the clock line (106) includes utilizing pull-up resistors (314, 316) for a high side impedance and at least a current sink (320) for low side impedance.

Example embodiments of the invention include a system (300) and/or apparatus for driving a clock signal. The system can include a DC positive supply voltage (306) and a DC negative supply voltage (324). The system and/or the apparatus may include an in-phase clock buffer output (304); an out-of-phase clock buffer output (302); a first transistor (308) of a differential pair having a high side (326) connected to the out-of-phase clock buffer output (302), wherein the out-of-phase clock buffer output (302) connects to the DC positive supply voltage (306) by a first pull-up resistor (314); a second transistor (310) of the differential pair having a high side (330) connected to the in-phase clock buffer output (304), wherein the in-phase clock buffer output (302) connects to the DC positive supply voltage (306) by a second pull-up resistor (316); a differential clock reference signal (312) for driving respective inputs of the first transistor (308) and the second transistor (310) of the differential pair; a current sink transistor (320) having a low side (336) connected to the DC negative supply voltage (324) by a third resistor (322); and a high side (334) connected to low sides (328, 332) associated with the first transistor (308) and the second transistor (310) of the differential pair. The output operational resistance of the differential clock buffer output (302, 304) is configured for approximately matching an impedance associated with a clock line (106).

In example embodiments, the first transistor (308) and the second transistor (310) of the differential pair are biased for operation in a forward active mode while conducting. According to example embodiments, the in-phase clock buffer output (304) and the out-of-phase clock buffer output (302) are configured for driving a clock line (106) with an alternating current signal having a fundamental frequency in the range of about 300 MHz to about 300 GHz. Example embodiments may include a back termination (520), wherein at least a portion of the resistance associated with the back termination is controllable. According to example embodiments, the back termination includes an N-channel MOSFET (520) for controlling resistance associated with at least a portion of the back termination. In an example embodiment, the first pull-up resistor (314) and the second pull-up resistor (316) are configured for matching, with the clock line (106, respective operational resistances of the out-of-phase clock buffer output (302) and the in-phase clock buffer output (304) when the respective first transistor (308) or the second transistor (310) of the differential pair is not conducting. In an example embodiment, one or more of a current sink transistor (320) or a current sink resistor (322) are configured for matching, with the clock line (106), respective operational resistances of the out-of-phase clock buffer output (302) and the in-phase clock buffer output (304) when the respective first transistor (308) or second transistor (310) of the differential pair is conducting.

According to example embodiments, certain technical effects can be provided, such as creating certain systems, methods, and apparatus that reduce the dependence of the clock buffer output impedance on the output signal dynamic range. Example embodiments of the invention can provide the further technical effects of providing systems, methods, and apparatus that reduce the temperature dependence of the clock buffer output impedance. Example embodiments of the invention can provide the further technical effects of providing systems, methods, and apparatus that provide an optimum approach to achieving improved signal integrity over the distributed clock tree network within the integrated circuit.

While certain embodiments of the invention have been described in connection with what is presently considered to be the most practical and various embodiments, it is to be understood that the invention is not to be limited to the disclosed embodiments, but on the contrary, is intended to cover various modifications and equivalent arrangements included within the scope of the appended claims. Although specific terms are employed herein, they are used in a generic and descriptive sense only and not for purposes of limitation.

This written description uses examples to disclose certain embodiments of the invention, including the best mode, and also to enable any person skilled in the art to practice certain embodiments of the invention, including making and using any devices or systems and performing any incorporated methods. The patentable scope of certain embodiments of the invention is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A method for driving a clock signal, the method comprising:
configuring a clock driver circuit with a differential clock buffer output connected to one or more clock lines;
matching an operational output resistance of the differential clock buffer output approximately with an input impedance associated with the one or more clock lines;
receiving a clock reference signal;
applying the clock reference signal to inputs associated with the differential clock driver circuit; and
driving the one or more clock lines with the differential clock buffer output.

2. The method of claim 1 wherein driving the one or more clock lines with the differential clock buffer output comprises one or more of: driving a single-ended clock line with one output of the differential clock buffer or driving a pair of clock lines with the differential clock buffer.

3. The method of claim 1, wherein applying the clock reference signal to inputs associated with the differential clock driver circuit comprises applying a single-ended or differential clock reference signal to base inputs of a differential transistor pair, wherein the differential transistor pair are biased for operation in a forward active mode while conducting.

4. The method of claim 1, wherein receiving the clock reference signal comprises receiving an alternating current signal having a fundamental frequency in the range of about 300 MHz to about 300 GHz for driving the one or more clock lines with an alternating current signal having a fundamental frequency in the range of about 300 MHz to about 300 GHz.

5. The method of claim 1, wherein configuring a clock driver circuit comprises configuring a back termination having a controllable resistance.

6. The method of claim 5, wherein configuring the back termination comprises configuring an N-channel or P-channel MOSFET for controlling resistance associated with at least a portion of the back termination.

7. The method of claim 1, wherein matching the operational resistance of the differential clock buffer output approximately with an impedance associated with the one or more clock lines comprises utilizing pull-up resistors for a high side impedance and at least a current sink for low side impedance.

8. A system for driving a clock signal, the system comprising:
a DC positive supply voltage;
a DC negative supply voltage;
an in-phase clock buffer output;
an out-of-phase clock buffer output;
a first transistor of a differential pair having a high side connected to the out-of-phase clock buffer output, wherein the out-of-phase clock buffer output connects to the DC positive supply voltage by a first pull-up resistor;
a second transistor of the differential pair having a high side connected to the in-phase clock buffer output, wherein the in-phase clock buffer output connects to the DC positive supply voltage by a second pull-up resistor;
a differential clock reference signal for driving respective inputs of the first transistor and the second transistor of the differential pair;
a current sink transistor having a low side connected to the DC negative supply voltage by a third resistor, and a high side connected to low sides associated with the first transistor and the second transistor of the differential pair;
wherein an output operational resistance of the differential clock buffer output is configured for approximately matching an impedance associated with a clock line.

9. The system of claim 8, wherein the first transistor and the second transistor of the differential pair are biased for operation in a forward active mode while conducting.

10. The system of claim 8, wherein the in-phase clock buffer output and the out-of-phase clock buffer output are configured for driving a clock line with an alternating current signal having a fundamental frequency in the range of about 300 MHz to about 300 GHz.

11. The system of claim 8, further comprising a back termination, wherein at least a portion of resistance associated with the back termination is controllable.

12. The system of claim 11, wherein the back termination comprises an N-channel or P-channel MOSFET for controlling resistance associated with at least a portion of the back termination.

13. The system of claim 8, wherein the first pull-up resistor and the second pull-up resistor are configured for matching, with the clock line, respective operational resistances of the out-of-phase clock buffer output and the in-phase clock buffer output when the respective first transistor or second transistor of the differential pair is not conducting.

14. The system of claim 8, wherein one or more of a current sink transistor or a current sink resistor are configured for matching, with the clock line, respective operational resistances of the out-of-phase clock buffer output and the in-phase clock buffer output when the respective first transistor or second transistor of the differential pair is conducting.

15. An apparatus for driving a clock signal, the apparatus comprising:
an in-phase clock buffer output;
an out-of-phase clock buffer output;
a first transistor of a differential pair having a high side connected to the out-of-phase clock buffer output, wherein the out-of-phase clock buffer output connects to a DC positive supply voltage by a first pull-up resistor;
a second transistor of the differential pair having a high side connected to the in-phase clock buffer output, wherein the in-phase clock buffer output connects to the DC positive supply voltage by a second pull-up resistor;
a current sink transistor having a low side connected to a DC negative supply voltage by a third resistor, and a high side connected to low sides associated with the first transistor and the second transistor of the differential pair;
a differential clock reference signal for driving respective inputs of the first transistor and the second transistor of the differential pair;
wherein an output operational resistance of the differential clock buffer output is configured for approximately matching an impedance associated with a clock line.

16. The apparatus of claim 15, wherein the first transistor and the second transistor of the differential pair are biased for operation in a forward active mode while conducting.

17. The apparatus of claim 15, wherein the in-phase clock buffer output and the out-of-phase clock buffer output are configured for driving a clock line with an alternating current signal having a fundamental frequency in the range of about 300 MHz to about 300 GHz.

18. The apparatus of claim 15, further comprising a back termination, wherein at least a portion of the resistance associated with the back termination is controllable, and wherein the back termination comprises an N-channel or P-channel MOSFET for controlling resistance associated with at least a portion of the back termination.

19. The apparatus of claim 15, wherein the first pull-up resistor and the second pull-up resistor are configured for matching, with the clock line, respective operational resistances of the out-of-phase clock buffer output and the in-phase clock buffer output when the respective first transistor or second transistor of the differential pair is not conducting.

20. The apparatus of claim 15, wherein one or more of a current sink transistor or a current sink resistor are configured for matching, with the clock line, respective operational resistances of the out-of-phase clock buffer output and the in-phase clock buffer output when the respective first transistor or second transistor of the differential pair is conducting.
